(19) United States
(12) Patent Application Publication
(10) Pub. No.: US 2026/0349329 A1
(43) Pub. Date: Nov. 5, 2026

(54) PELLICLE STRUCTURE FOR EUV LITHOGRAPHY AND METHODS OF MANUFACTURING THEREOF

(71) Applicant: Taiwan Semiconductor Manufacturing Company, Ltd., Hsinchu (TW)

(72) Inventors: Ting-Pi SUN, Taichung (TW); Huan-Ling LEE, Hsinchu (TW); Hsin-Chang LEE, Zhubei (TW)

(73) Assignee: Taiwan Semiconductor Manufacturing Company, Ltd., Hsinchu (TW)

(21) Appl. No.: 19/745,016

(22) Filed: Jul. 16, 2026

Related U.S. Application Data
(63) Continuation of application No. 18/668,052, filed on May 17, 2024.
(60) Provisional application No. 63/621,806, filed on Jan. 17, 2024.

(51) Int. Cl. G03F 1/64; B82Y 30/00; G03F 1/76

(52) U.S. Cl. CPC G03F 1/64; G03F 1/76; B82Y 30/00

(57) ABSTRACT

A method of manufacturing a semiconductor device includes heating a pellicle disposed over a photomask. Actinic radiation is passed through the pellicle to selectively expose a photoresist layer on a substrate. The selectively exposed photoresist layer is developed to form a pattern in the photoresist layer.

### RELATED APPLICATIONS

This application is a continuation application of U.S. application Ser. No. 18/668,052 filed May 17, 2024, which claims priority of U.S. Provisional Patent Application No. 63/621,806 filed Jan. 17, 2024, the entire contents of each of which are incorporated herein by reference.

### BACKGROUND

A pellicle is a thin transparent film stretched over a frame that is glued over a photomask to protect the photomask from damage, dust and/or moisture. In extreme ultraviolet (EUV) lithography, a pellicle having a high transparency in the EUV wavelength region, a high mechanical strength and a low or no contamination is generally applied.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B show pellicles for an EUV photomask in accordance with embodiments of the present disclosure.

FIGS. 2A, 2B, 2C, and 2D show various views of multiwall nanotubes in accordance with embodiments of the present disclosure.

FIGS. 3A, 3B, and 3C show a manufacturing process of a network membrane in accordance with an embodiment of the present disclosure.

FIG. 3D shows a manufacturing process of a network membrane, and FIG. 3E shows a flow chart thereof in accordance with an embodiment of the present disclosure.

FIGS. 4A and 4B show a cross sectional view and a plan (top) view of one of the various stages for manufacturing a pellicle for an EUV photomask in accordance with an embodiment of the present disclosure.

FIGS. 5A and 5B show a cross sectional view and a plan (top) view of one of the various stages for manufacturing a pellicle for an EUV photomask in accordance with an embodiment of the present disclosure.

FIGS. 6A and 6B show a cross sectional view and a plan (top) view of one of the various stages for manufacturing a pellicle for an EUV photomask in accordance with an embodiment of the present disclosure.

FIGS. 7A and 7B show flow charts for manufacturing a pellicle/photomask structure in accordance with embodiments of the present disclosure.

FIGS. 8A and 8B show schematic views of a pellicle according to an embodiment of the present disclosure.

FIGS. 9A, 9B, 9C, and 9D show schematic views of a method of manufacturing a pellicle according to an embodiment of the present disclosure. FIG. 9E shows a cross sectional view of a pellicle according to an embodiment of the present disclosure.

FIGS. 10A, 10B, 10C, and 10D show schematic views of a method of manufacturing a pellicle according to an embodiment of the present disclosure. FIG. 10E shows a cross sectional view of a pellicle according to an embodiment of the present disclosure.

FIGS. 11A, 11B, and 11C show schematic views of a method of manufacturing a pellicle according to an embodiment of the present disclosure. FIG. 11D shows a cross sectional view of a pellicle according to an embodiment of the present disclosure.

FIGS. 12A and 12B show plan views of a pellicle frame with conductive electrodes according to an embodiment of the present disclosure. FIG. 12C is a cross sectional view of a pellicle according to an embodiment of the present disclosure.

FIGS. 13A and 13B show plan views of a pellicle frame with conductive electrodes according to an embodiment of the present disclosure. FIGS. 13C and 13D are cross sectional views of a pellicle according to embodiments of the present disclosure. FIG. 13E shows a plan view of a pellicle frame with conductive electrodes according to an embodiment of the present disclosure.

FIG. 14 shows a schematic view of a pellicle/photomask structure according to an embodiment of the present disclosure.

FIGS. 15A, 15B, and 15C show flow charts for manufacturing a semiconductor device in accordance with embodiments of the present disclosure.

FIG. 16 shows schematic views illustrating formation of a bundle of nanotubes according to an embodiment of the present disclosure.

FIG. 17 shows schematic views illustrating removal or conversion of amorphous carbon according to an embodiment of the present disclosure.

FIGS. 18A, 18B, 18C, 18D, and 18E show various views of removal of residual catalysts and formation of a bundle of nanotubes in accordance with embodiments of the present disclosure.

FIG. 19 shows a schematic view illustrating the removal of contaminants from a pellicle according to an embodiment of the present disclosure.

FIG. 20 shows a schematic view illustrating the decomposition of contaminants from a pellicle according to an embodiment of the present disclosure.

FIGS. 21A and 21B show schematic views illustrating the removal of wrinkles from a nanotube membrane according to an embodiment of the present disclosure.

FIG. 22A and FIG. 22B are diagrams of a controller according to some embodiments of the disclosure.

FIG. 23A shows a flowchart of a method making a semiconductor device, and FIGS. 23B, 23C, 23D, and 23E show a sequential manufacturing operation of a method of manufacturing a semiconductor device according to embodiments of present disclosure.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity. In the accompanying drawings, some layers/features may be omitted for simplification.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.” Further, in the following fabrication process, there may be one or more additional operations in between the described operations, and the order of operations may be changed. In the present disclosure, the phrase “at least one of A, B and C” means either one of A, B, C, A+B, A+C, B+C or A+B+C, and does not mean one from A, one from B and one from C, unless otherwise explained. Materials, configurations, structures, operations and/or dimensions explained with one embodiment can be applied to other embodiments, and detailed description thereof may be omitted.

EUV lithography is one of the crucial techniques for extending Moore's law. However, due to wavelength scaling from 193 nm (ArF) to 13.5 nm, the EUV light source suffers from strong power decay due to environmental adsorption. Even though a stepper/scanner chamber is operated under vacuum to prevent strong EUV adsorption by gas, maintaining a high EUV transmittance from the EUV light source to a wafer is still an important factor in EUV lithography.

A pellicle generally requires a high transparency and a low reflectivity. In UV or DUV lithography, the pellicle film is made of a transparent resin film. In EUV lithography, however, a resin based film would not be acceptable, and a non-organic material, such as a polysilicon, silicide or metal film, is used in some embodiments.

Carbon nanotubes (CNTs) are one of the materials suitable for a pellicle for an EUV photomask because CNTs have a high EUV transmittance of more than 96.5%. Generally, a pellicle for an EUV reflective mask requires the following properties: (1) Long life time in a hydrogen radical rich operation environment in an EUV stepper/scanner; (2) Strong mechanical strength to minimize the sagging effect during vacuum pumping and venting operations; (3) A high or perfect blocking property for particles larger than about 20 nm (killer particles); and (4) Good heat dissipation to prevent the pellicle from being burnt out by EUV radiation. Other nanotubes made of a non-carbon based material are also usable for a pellicle for an EUV photomask. In some embodiments of the present disclosure, a nanotube is a one dimensional elongated tube having a dimeter in a range from about 0.5 nm to about 100 nm.

In the present disclosure, a pellicle for an EUV photomask includes a network membrane having a plurality of nanotubes that form a mesh structure. Further, a method of treating the network membrane to remove contaminants and to increase mechanical strength is also disclosed.

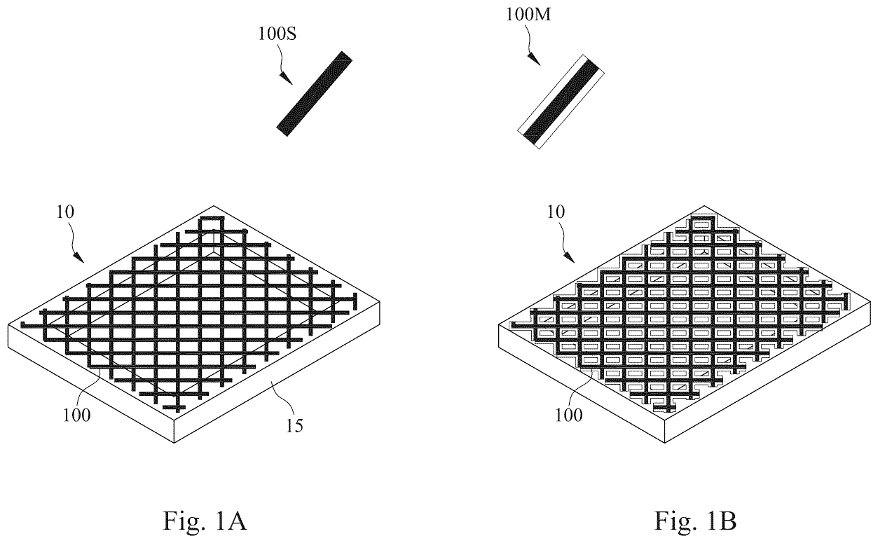

FIGS. 1A and 1B show EUV pellicles 10 in accordance with an embodiment of the present disclosure. In some embodiments, a pellicle 10 for an EUV reflective mask includes a main network membrane 100 disposed over and attached to a pellicle frame 15. In some embodiments, the main network membrane 100 is a transparent membrane transparent to electromagnetic radiation, such as EUV radiation. In some embodiments, the transparent membrane 100 has an EUV transmittance of more than 96.5%. The transparent membrane 100 may be opaque to some electromagnetic wavelengths, such as infrared or visible radiation and transparent to other electromagnetic wavelengths, such as EUV radiation or X-ray radiation. In some embodiments, as shown in FIG. 1A, the main network membrane 100 includes a plurality of single wall nanotubes 100S, and in other embodiments, as shown in FIG. 1B, the main network membrane 100 includes a plurality of multiwall nanotubes 100M. In some embodiments, the single wall nanotubes are carbon nanotubes. In other embodiments, the single wall nanotubes are nanotubes made of a non-carbon based material. In some embodiments, the non-carbon based material includes at least one of boron nitride (BN), SiC or transition metal dichalcogenides (TMDs), represented by MX₂, where M=Mo, W, Pd, Pt, and/or Hf, and X=S, Se and/or Te. In some embodiments, a TMD is one of MoS₂, MoSe₂, WS₂ or WSe₂.

In some embodiments, some of the single wall nanotubes form a bundle of nanotubes attached to each other.

In some embodiments, a multiwall nanotube is a co-axial nanotube having two or more tubes co-axially surrounding an inner tube(s). In some embodiments, the main network membrane 100 includes only one type of nanotubes (single wall/multiwall, or material) and in other embodiments, different types of nanotubes form the main network membrane 100. In some embodiments, the multiwall nanotubes are multiwall carbon nanotubes. In some embodiments, some of the multiwall nanotubes form a bundle of nanotubes attached to each other.

In some embodiments, a pellicle (support) frame 15 is attached to the main network membrane 100 to maintain a space between the main network membrane of the pellicle and an EUV mask (pattern area) when mounted on the EUV mask. The pellicle frame 15 of the pellicle is attached to the surface of the EUV photomask with an appropriate bonding material. In some embodiments, the bonding material is an adhesive, such as an acrylic or silicon-based glue or a cross link type adhesive. The size of the frame structure is larger than the area of the black borders of the EUV photomask so that the pellicle covers not only the circuit pattern area of the photomask but also the black borders.

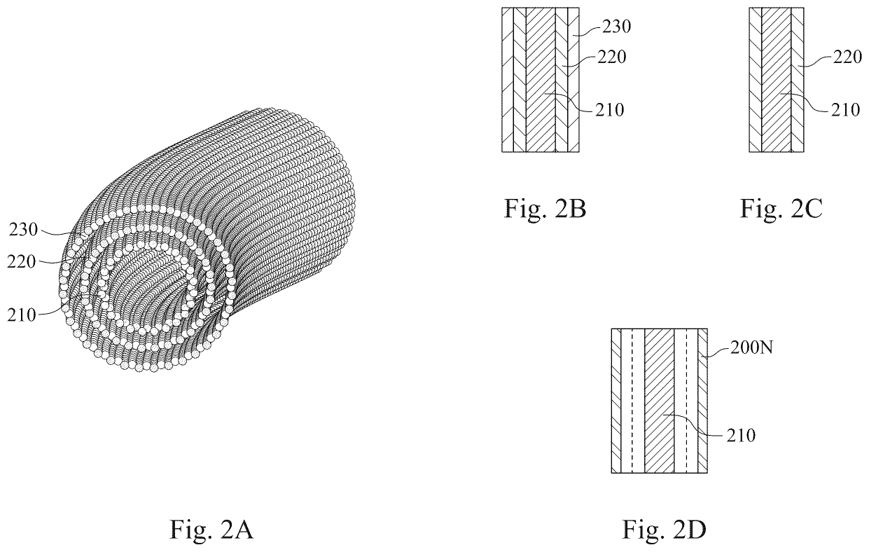

FIGS. 2A, 2B, 2C, and 2D show various views of multiwall nanotubes in accordance with embodiments of the present disclosure.

In some embodiments, the nanotubes in the main network membrane 100 include multiwall nanotubes, which are also referred to as co-axial nanotubes. FIG. 2A shows a perspective view of a multiwall co-axial nanotube having three tubes 210, 220, and 230 and FIG. 2B shows a cross sectional view thereof. In some embodiments, the inner tube 210 and outer tubes 220 and 230 are carbon nanotubes. In other embodiments, one of more of the inner or two outer tubes are non-carbon based nanotubes, such as boron nitride nanotubes.

The number of tubes of the multiwall nanotubes is not limited to three. In some embodiments, the multiwall nanotube has two co-axial nanotubes as shown in FIG. 2C, and in other embodiments, the multiwall nanotube includes the innermost tube 210 and the first to N-th nanotubes including the outermost tube 200N, where N is a natural number from 1 to about 20, as shown in FIG. 2D. In some embodiments, N ranges from 5 to 10. In some embodiments, at least one of the first to the N-th outer layers is a nanotube coaxially surrounding the innermost nanotube 210. In some embodiments, all the innermost tube 210 and the first to the N-th outer layers are carbon nanotubes. In other embodiments, one or more of the tubes are non-carbon based nanotubes.

In some embodiments, a diameter of the innermost nanotube is in a range from about 0.5 nm to about 20 nm and is in a range from about 1 nm to about 10 nm in other embodiments. In some embodiments, a diameter of the multiwall nanotubes (i.e., diameter of the outermost tube) is in a range from about 3 nm to about 40 nm and is in a range from about 5 nm to about 20 nm in other embodiments. In some embodiments, a length of the multiwall nanotube is in a range from about 0.5 μm to about 50 μm and is in a range from about 1.0 μm to about 20 μm in other embodiments.

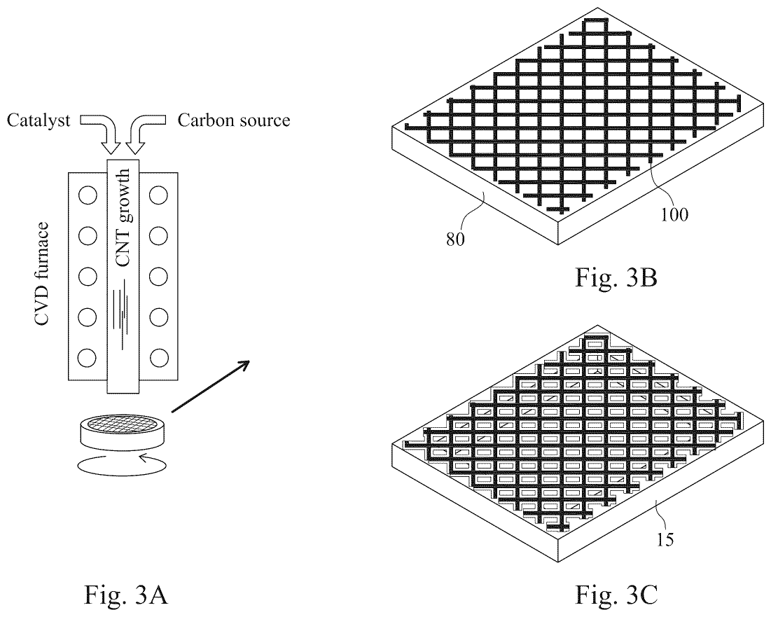

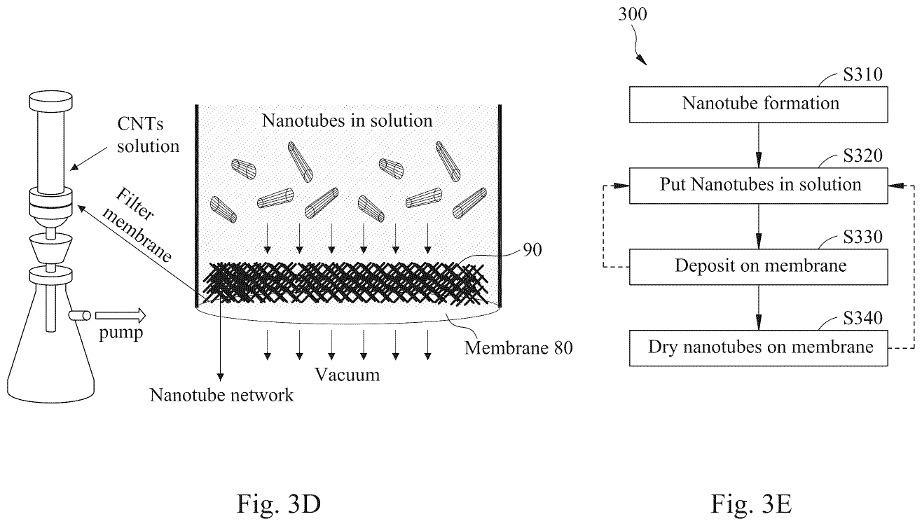

FIGS. 3A, 3B, and 3C show a manufacturing method of nanotube network membranes for a pellicle in accordance with embodiments of the present disclosure.

In some embodiments, carbon nanotubes are formed by a chemical vapor deposition (CVD) process. In some embodiments, a CVD process is performed by using a vertical furnace as shown in FIG. 3A, and synthesized nanotubes are deposited on a support membrane 80 as shown in FIG. 3B. In some embodiments, carbon nanotubes are formed from a carbon source gas (precursor) using an appropriate catalyst, such as Fe or Ni. Then, the network membrane 100 formed over the support membrane 80 is detached from the support membrane 80, and transferred on to the pellicle frame 15 as shown in FIG. 3C. In some embodiments, a stage or a susceptor, on which the support membrane 80 is disposed, rotates continuously or intermittently (step-by-step manner) so that the synthesized nanotubes are deposited on the support membrane 80 with different or random directions.

FIG. 3D shows a manufacturing method of a network membrane and FIG. 3E shows a flow chart of the manufacturing method 300 in accordance with an embodiment of the present disclosure. The nanotubes are formed by CVD methods in some embodiments, as previously explained, in operation S310. In some embodiments, the nanotubes are formed by various other methods, such as arc-discharge or laser ablation methods.

The nanotubes are dispersed in a solution in operation S320, as shown in FIG. 3D. The solution includes a solvent, such as water or an organic solvent, and a surfactant, such as sodium dodecyl sulfate (SDS). The nanotubes are one type or two or more types of nanotubes (material and/or wall numbers).

As shown in FIG. 3D, a support membrane 80 is placed between a chamber or a cylinder in which the nanotube dispersed solution is disposed and a vacuum chamber. In some embodiments, the support membrane is an organic or inorganic porous or mesh material. In some embodiments, the support membrane is a woven or non-woven fabric. In some embodiments, the support membrane has a circular shape in which a pellicle size of a 150 mm×150 mm square (the size of an EUV mask) can be placed.

As shown in FIG. 3D, the pressure in the vacuum chamber is reduced so that a pressure is applied to the solvent in the chamber or cylinder. Since the mesh or pore size of the support membrane is sufficiently smaller than the size of the nanotubes, the nanotubes are captured by the support membrane while the solvent passes through the support membrane in operation S330. The support membrane on which the nanotubes are deposited is detached from the filtration apparatus of FIG. 3D and then is dried in operation S340. In some embodiments, the deposition by filtration is repeated to obtain a desired thickness of the nanotube network layer. In some embodiments, after the deposition of the nanotubes in the solution, other nanotubes are dispersed in the same or new solution and the filter-deposition is repeated. In other embodiments, after the nanotubes are dried, another filter-deposition is performed. In the repetition, the same type of nanotubes is used in some embodiments, and different types of nanotubes are used in other embodiments. In some embodiments, the nanotubes dispersed in the solution include multiwall nanotubes.

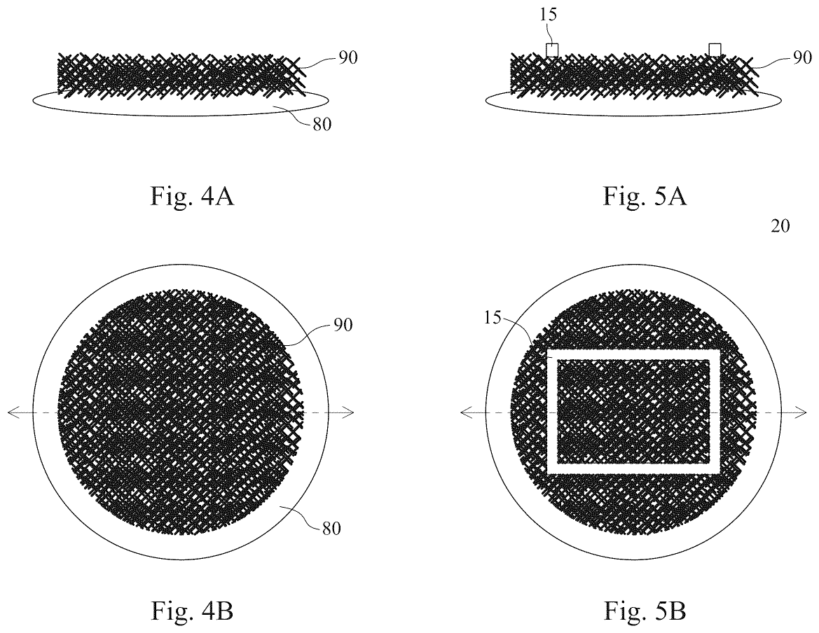

FIGS. 4A and 4B to 6A and 6B show cross sectional views (the “A” figures) and plan (top) views (the “B” figures) of the various stages for manufacturing a pellicle for an EUV photomask in accordance with an embodiment of the present disclosure. It is understood that additional operations can be provided before, during, and after the processes shown by FIGS. 4A-6B, and some of the operations described below can be replaced or eliminated, for additional embodiments of the method. The order of the operations/processes may be interchangeable. Materials, configurations, methods, processes and/or dimensions as explained with respect to the foregoing embodiments are applicable to the following embodiments, and the detailed description thereof may be omitted.

As shown in FIGS. 4A and 4B, a nanotube layer 90 is formed on a support membrane 80 by one or more methods as explained above. In some embodiments, the nanotube layer 90 includes single wall nanotubes, multiwall nanotubes, or mixtures thereof. In some embodiments, the nanotube layer 90 includes single wall nanotubes only. In some embodiments, the nanotubes are carbon nanotubes.

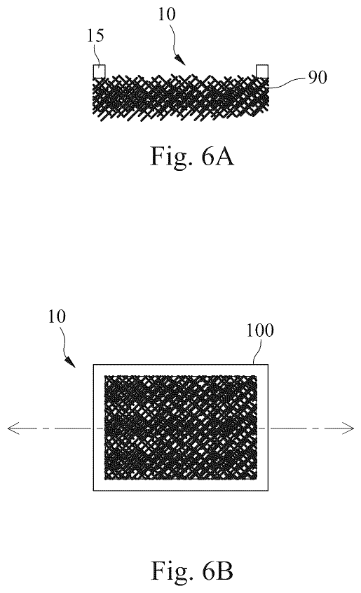

Then, as shown in FIGS. 5A and 5B, a pellicle frame 15 is attached to the nanotube layer 90. In some embodiments, the pellicle frame 15 is formed of one or more layers of a crystalline silicon, a polysilicon, a silicon oxide, a silicon nitride, an aluminum oxide, or a ceramic material. In some embodiments, as shown in FIG. 5B, the pellicle frame 15 has a rectangular (including square) frame shape, which is larger than the black border area of an EUV mask and smaller than the substrate of the EUV mask. In some embodiments, the pellicle frame is attached to the nanotube layer by a cold welding operation.

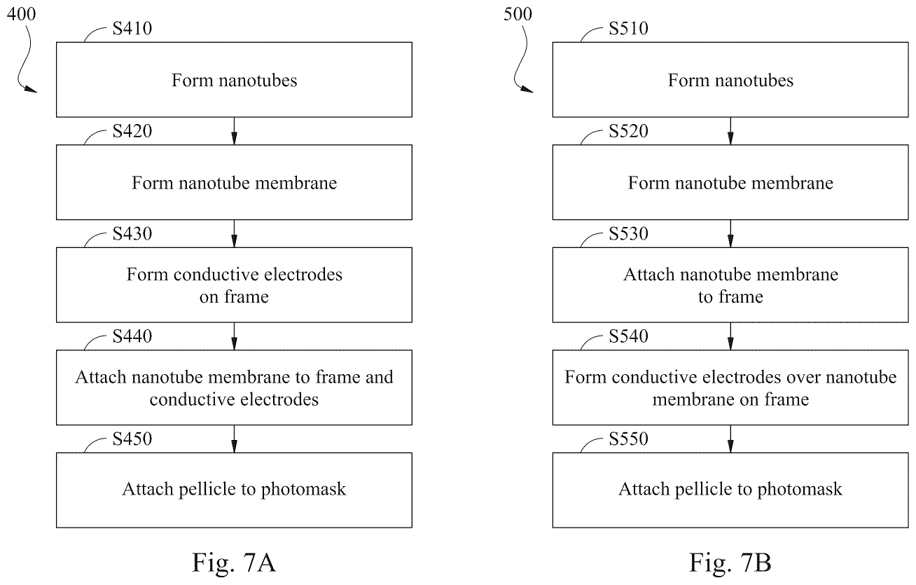

Next, as shown in FIGS. 6A and 6B, the nanotube layer 90 and the support membrane 80 are cut into a rectangular shape having the same size as or slightly larger than the pellicle frame 15, and then the support membrane 80 is detached or removed, in some embodiments. When the support membrane 80 is made of an organic material, the support membrane 80 is removed by wet etching using an organic solvent.

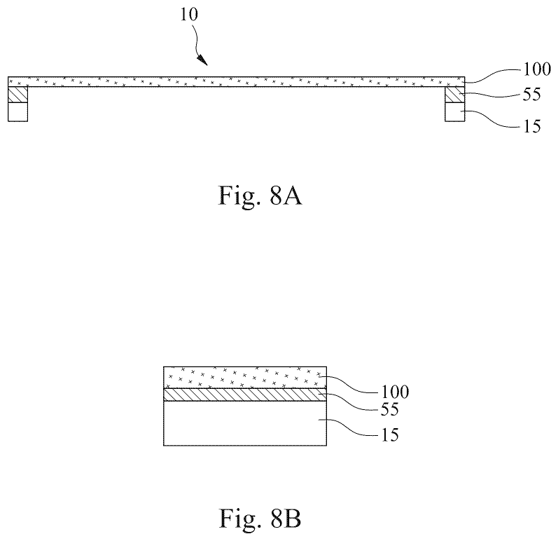

FIGS. 7A and 7B are flow charts showing methods of manufacturing pellicle/photomask structures according to embodiments of the present disclosure. It is understood that additional operations can be provided before, during, and after the processes shown in FIGS. 7A and 7B, and some of the operations described below can be replaced or eliminated, for additional embodiments of the method. The order of the operations/processes may be interchangeable.

In the flow of FIG. 7A, nanotubes are formed according to any of the methods disclosed above in operation S410, and a nanotube membrane is formed according to any of the methods disclosed above in operation S420. Then, electrically conductive electrodes are formed on the pellicle frame in operation S430. The nanotube membrane is attached to the pellicle frame and the conductive electrodes in operation S440 to form a pellicle, and the pellicle frame is subsequently attached to the photomask in operation S450.

In another embodiment of the disclosure the pellicle/photomask structure is formed in a different sequence of operations 500, as shown in the flow of FIG. 7B. As in the flow of FIG. 7A, the nanotubes are formed according to any of the methods disclosed above in operation S510, and a nanotube membrane is formed according to any of the methods disclosed above in operation S520. Then, the nanotube membrane is attached to the pellicle frame in operation S530. The conductive electrodes are subsequently formed over the nanotube membrane in operation S540 to form a pellicle. Then, the pellicle frame is attached to the photomask in operation S550 to form the pellicle/photomask structure.

The methods of manufacturing the pellicle/photomask structure will subsequently be explained in further detail herein.

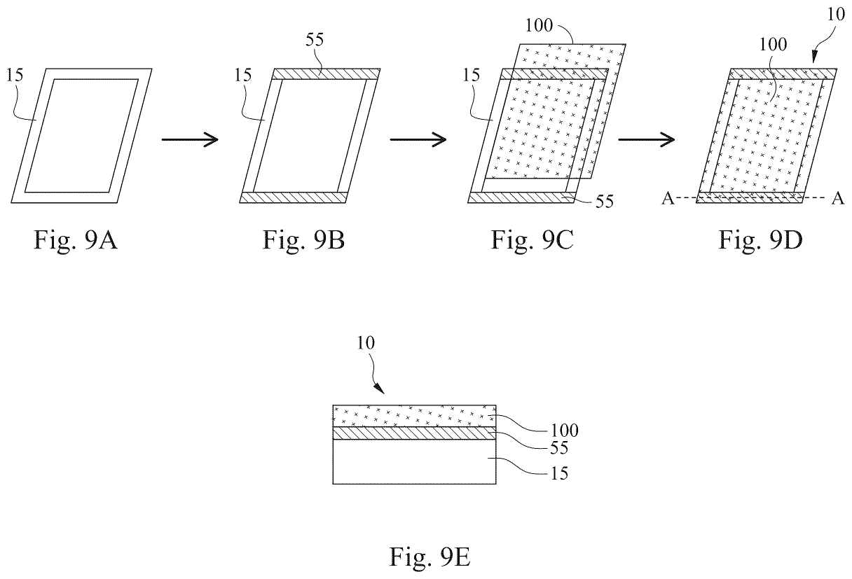

FIGS. 8A and 8B show schematic views of a pellicle according to an embodiment of the present disclosure. FIG. 8A is a cross sectional view across the pellicle 10, showing the nanotube membrane disposed over conductive electrodes 55 formed on the pellicle frame 15. FIG. 8B is a cross sectional view along the pellicle frame 15.

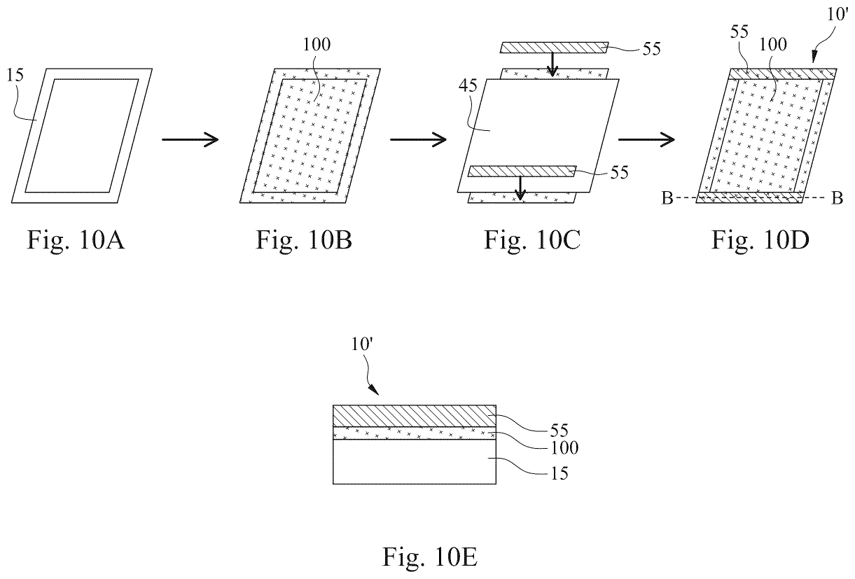

FIGS. 9A, 9B, 9C, and 9D show schematic views of a method of manufacturing a pellicle according to an embodiment of the present disclosure. An insulating pellicle frame 15 is provided, as shown in FIG. 9A. The pellicle frame 15 may be electrically and thermally insulating. In some embodiments, the pellicle frame 15 is made of crystalline silicon, polysilicon, silicon oxide, silicon nitride, aluminum oxide, a ceramic material, or any other suitable electrically and thermally insulating material.

Two opposing sides of the frame 15 are coated with a conductive material to form conductive electrodes 55, as shown in FIG. 9B. The conductive material of the electrodes may be an electrically conductive material having a high melting point. In some embodiments, the conductive material is a metal, including Cu, Au, Ni, Ag, and alloys thereof, and any other suitable metal. In some embodiments, the conductive material includes other conductive materials, such as graphite. The conductive material is deposited over the frame by any suitable deposition method, including chemical vapor deposition (CVD), atomic layer deposition (ALD), physical vapor deposition (PVD), electroplating, and electroless plating. Two opposing sides of the frame 15 are coated with the conductive material so that a subsequently formed pellicle can be heated uniformly by electrical currents passing through the pellicle from one side to the other side.

A nanotube membrane 100, prepared by any of the methods disclosed herein, is attached to the frame 15 and conductive electrodes 55, as shown in FIG. 9C to form the pellicle in FIG. 9D. FIG. 9E shows a cross sectional view of the pellicle 10 along line A-A showing the nanotube membrane 100 disposed over the conductive electrode 55 and the pellicle frame 15.

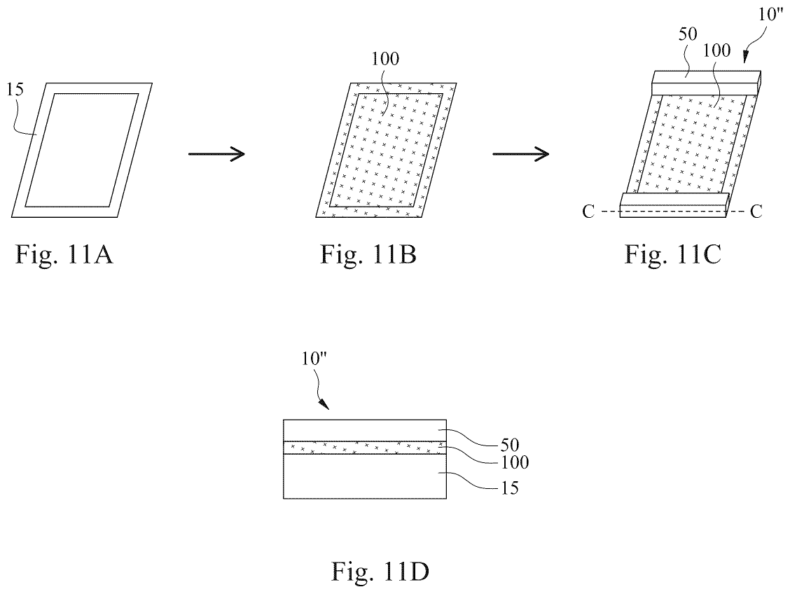

FIGS. 10A, 10B, 10C, and 10D show schematic views of a method of manufacturing a pellicle according to an embodiment of the present disclosure. An insulating pellicle frame 15 is provided, as shown in FIG. 10A. The pellicle frame 15 is made of any of the electrically and thermally insulating materials disclosed above.

A nanotube membrane 100, prepared by any of the methods disclosed herein, is disposed over and attached to the frame 15, as shown in FIG. 10B. Then, a mask or jig 45 is disposed over the nanotube membrane exposing opposing sides of the frame 15. The two exposed opposing sides of the frame 15 are coated with the conductive material in FIG. 10C to form the conductive electrodes 55. The mask or jig 45 is removed in FIG. 10D illustrating the pellicle 10′. The electrodes may be formed of any of the high melting point electrically conductive materials disclosed above. FIG. 10E shows a cross sectional view of the pellicle 10′ along line B-B showing the conductive electrode 55 disposed over the nanotube membrane 100 and the pellicle frame 15.

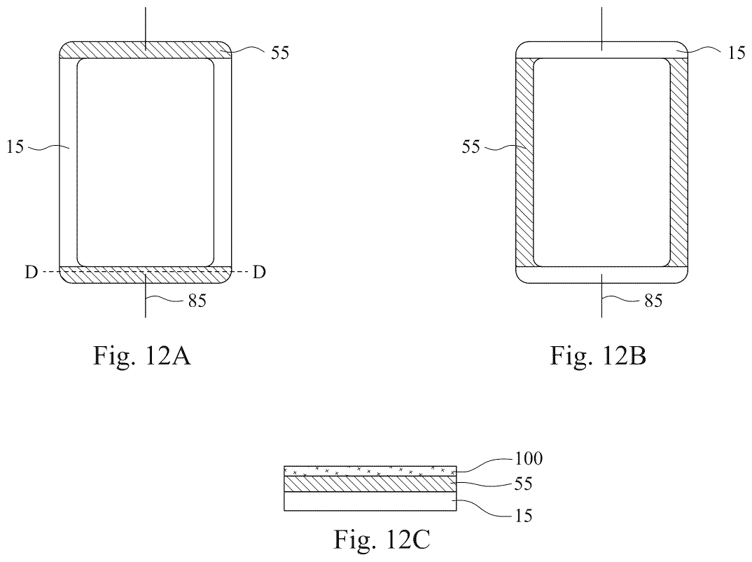

FIGS. 11A, 11B, and 11C show schematic views of a method of manufacturing a pellicle according to an embodiment of the present disclosure. An insulating pellicle frame 15 is provided, as shown in FIG. 11A. The pellicle frame 15 is made of any of the electrically and thermally insulating materials disclosed above.

A nanotube membrane 100, prepared by any of the methods disclosed herein, is disposed over and attached to the frame 15, as shown in FIG. 11B. Then, conductive plates 50 are disposed over and attached to opposing sides of the frame 15 to form the pellicle 10″, as shown in FIG. 11C. The conductive plates 50 may be formed of any of materials disclosed above for use in the conductive electrodes 55. FIG. 11D shows a cross sectional view of the pellicle 10″ along line C-C showing the conductive electrode 55 disposed over the nanotube membrane 100 and the pellicle frame 15.

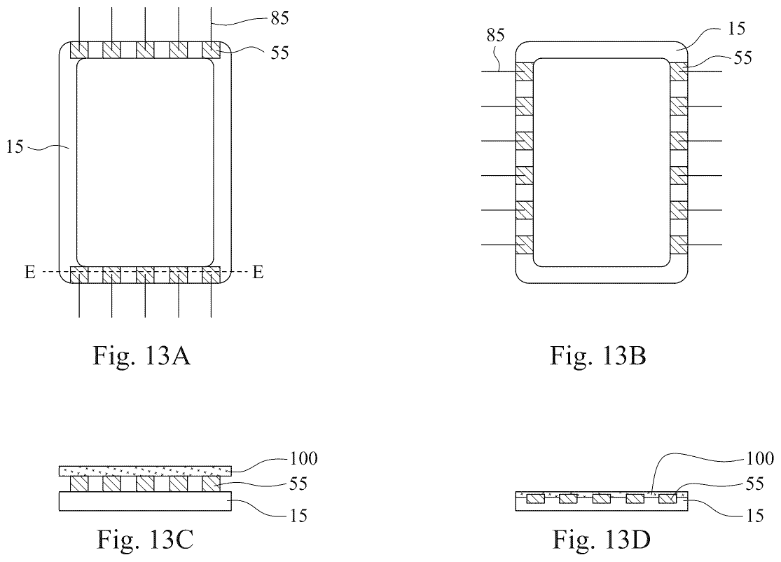

FIGS. 12A and 12B show plan views of a pellicle frame with conductive electrodes according to an embodiment of the present disclosure. In some embodiments, the pellicle frame 15 is rectangular shaped, and the conductive electrodes 55 are formed on the shorter opposing sides, as shown in FIG. 12A. In other embodiments, the conductive electrodes are formed on the longer opposing sides of the frame, as shown in FIG. 12B. Conductive leads 85, such as wires, are attached to the conductive electrodes 55. The conductive leads 85 may be formed of any suitable conductive material, including copper, aluminum, and alloys thereof. The conductive leads are attached to a power supply in some embodiments. FIG. 12C is a cross sectional view of the pellicle along line D-D including the nanotube membrane 100 disposed over the conductive electrodes and the frame.

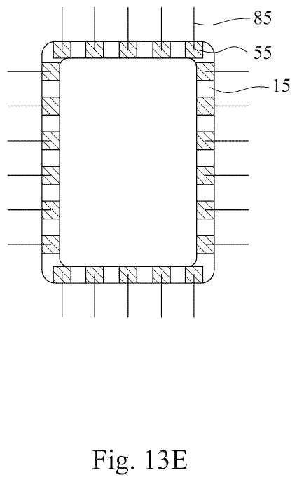

In some embodiments, a plurality of electrodes 55 are disposed on the pellicle frame, as shown in FIGS. 13A and 13B. Conductive leads 85 are attached to each of the plurality of electrodes 55. In some embodiments the plurality of electrodes 55 are disposed on the shorter sides of the rectangular frame 15, as shown in FIG. 13A, and in other embodiments, the plurality of electrodes 55 are disposed on the longer sides of the rectangular frame, as shown in FIG. 13B. Five electrodes are shown on each side of the frame, but the present disclosure is not limited to five electrodes on each side. The number of electrodes on each opposing side of the frame ranges from two to ten in some embodiments, and more than ten in other embodiments. The electrodes are made of any of the conductive materials disclosed herein.

The conductive electrodes 55 may be formed by any suitable technique, including masking portions of the frame and depositing the conductive material over the exposed portions of the frame, and then disposing the nanotube membrane 100 over the conductive electrodes 55 and the frame, as shown in FIG. 13C. FIG. 13C is a cross sectional view along line E-E after the carbon nanotube membrane is disposed over the conductive electrodes 55 and the frame 15. In other embodiments, a plurality of recesses is formed in the frame, and the conductive material is deposited in the recesses. The recesses are formed by photolithographic and etching techniques in some embodiments. The conductive material is subsequently deposited into the recess, the electrodes are planarized, such as by a etch back operation or a chemical mechanical polishing operation. Then, the nanotube membrane 100 is disposed over the frame 15 and conductive electrodes 55. As shown in the cross sectional view along line E-E, in FIG. 13D, the nanotube membrane 100 contacts both the frame 15 and the conductive electrodes 55. In some embodiments, the nanotube membrane 100 is flush to the frame 15 and the conductive electrodes 55.

In some embodiments, the electrodes 55 are formed on each side of the frame 15, as shown in FIG. 13E. The electrodes 55 may be formed of any of the same materials and operations as disclosed herein.

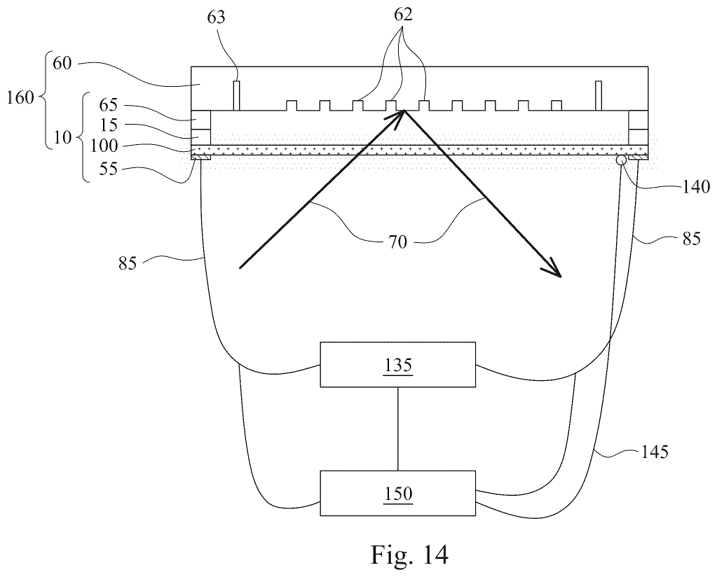

The pellicle 10 is subsequently attached to the surface of an EUV photomask 60 through the insulating frame 15 with an appropriate bonding material 65. In some embodiments, the bonding material is an adhesive, such as an acrylic or silicon-based glue or a cross link type adhesive. The size of the frame 15 is larger than the area of the black borders 63 of the EUV photomask 60 so that the pellicle covers not only the circuit pattern area 62 of the photomask 60 but also the black borders 63, as shown in FIG. 14.

The conductive leads are connected to a power supply 135 or a controller 150 during semiconductor device manufacturing operations. During operation of an EUV photolithographic exposure apparatus, including a stepper or a scanner, an electric current is provided to the conductive electrodes 55 from a power supply 135 via the conductive leads 85. The electrical current may be alternating current (AC) or direct current (DC). In some embodiments a voltage of about 5 V to about 500 V is applied to the conductive electrodes 55. In some embodiments, a voltage of about 50 V to about 400 V is applied to the conductive electrodes 55, and in other embodiments, a voltage of about 100 V to 300 V is applied to the conductive electrodes 55. The electric current heats the pellicle's nanotube membrane by Joule heating.

Heating the pellicle's nanotube membrane improves the photolithographic exposure operation. Heating the nanotube membrane removes impurities from pellicle thereby maintaining high EUV radiation transmission through the pellicle in some embodiments. In some embodiments, the electric field across the nanotube membrane repels contaminant particles from the membrane due to electrostatic force, which also prevents contaminant particles from approaching the pellicle. The heated nanotube membrane may also burn or decompose contaminant particles that have contaminant particles attached to the pellicle. Heating the nanotube membrane removes metal-based catalysts, such as the Fe catalysts used in the production of the carbon nanotubes. In some embodiments, the heating the nanotube membrane provides an increase of up to 1% in EUV radiation 70 transmission through the pellicle 10.

In some embodiments, the nanotube membrane 100 is heated to a temperature of about 500° C. to about 2000° C. In other embodiments, the nanotube membrane is heated to a temperature of about 750° C. to about 1750° C., while in other embodiments the nanotube membrane is heated to a temperature of about 1000° C. to about 1500° C. Heating the nanotube membrane to temperatures below the disclosed ranges may result in insufficient contaminant removal from the nanotube membrane 100. Heating the nanotube membrane at temperatures above the disclosed range may damage the pellicle/photomask structure, and may result in decreased photolithographic performance and yield. In some embodiments, a different amount of power, including no power, is applied to the various electrodes 55. In some embodiments, each electrode 55 is separately controlled by the controller 150. Only the nanotube membrane is heated by the Joule heating. The insulating frame 15 insulates the photomask 60 from the heated nanotube membrane and the electric current applied to conductive electrodes 55 in embodiments of the disclosure.

In some embodiments a temperature sensor 140 is positioned adjacent the pellicle 10 to monitor the temperature. The temperature sensor 140 is in communication with the controller via a conductive lead 145 in some embodiments, and communicates with the controller wirelessly in other embodiments. The power supplied to the pellicle 10, and thus, the temperature of the nanotube membrane is controlled by a controller 150 in some embodiments.

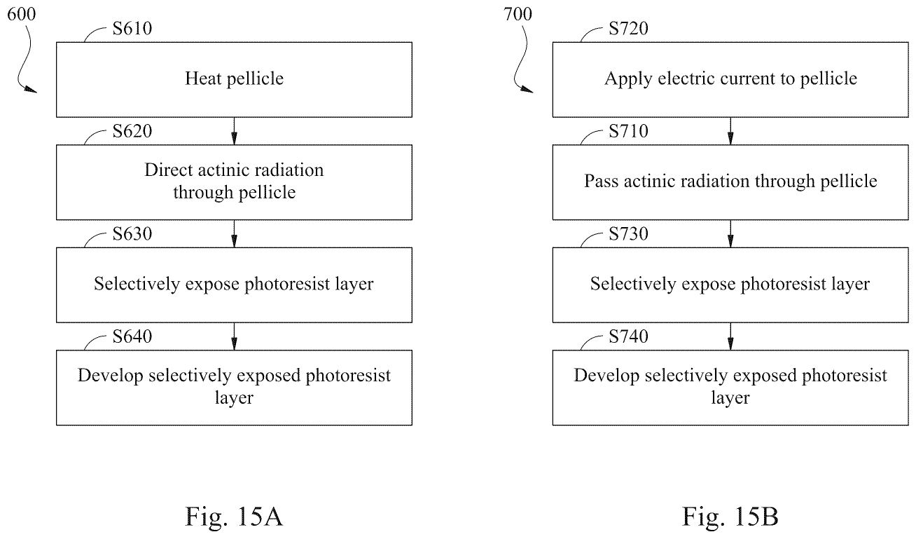

A method 600 of manufacturing a semiconductor device according to an embodiment of the disclosure is illustrated in the flow chart of FIG. 15A. A pellicle 10 disposed over a photomask 60 is heated in operation S610. Actinic radiation 70, is directed through the pellicle in operation S630. In some embodiments, the photomask 60 is an EUV reflective photomask. The EUV radiation 70 is provided by an EUV radiation source. The EUV radiation 70 passes through nanotube membrane 100, is reflected off the photomask 60 in a patternwise manner, and is directed through the nanotube membrane 100 a second time, to selectively expose a photoresist layer disposed over a substrate in operation S630. In some embodiments, the substrate is a semiconductor wafer. The selectively exposed photoresist layer is subsequently developed in operation S640 to form a pattern in the photoresist layer.

A method 700 of manufacturing a semiconductor device according to another embodiment of the disclosure is illustrated in the flow chart of FIG. 15B. Actinic radiation 70 reflected from photomask 60 passes through a pellicle 10 disposed over the photomask in operation S710. An electric current is applied to the pellicle 10 in operation S720 while the actinic radiation 70 passes through the pellicle 10. The actinic radiation 70 passing through the pellicle 10 selectively exposes a photoresist layer disposed on a substrate in operation S730. In some embodiments, the substrate is a semiconductor wafer. The selectively exposed photoresist layer is subsequently developed in operation S740 to form a pattern in the photoresist layer.

A method 800 of manufacturing a semiconductor device according to another embodiment of the disclosure is illustrated in the flow chart of FIG. 15C. A pellicle/photomask structure 160 is placed in a photolithography exposure apparatus in operation S810. The pellicle/photomask structure 160 includes a pellicle 10 disposed over a photomask 60. The pellicle 10 is heated by applying an electric current to the pellicle 10 in operation S820. Actinic radiation 70 is directed through the pellicle 10 to selectively expose a photoresist layer disposed on a substrate in operation S830. The selectively exposed photoresist layer is subsequently developed in operation S840 to form a pattern in the photoresist layer.

In some embodiments, the photolithography exposure apparatus is an EUV lithography apparatus, including a scanner or stepper. In some embodiments, the portion of the lithography apparatus including the pellicle/photomask structure 160 is under a vacuum during the photolithographic exposure operation. In some embodiments, the pressure in the vacuum is equal to or lower than 10 Pa, in other embodiments, the pressure ranges from 0.1 Pa to 10 Pa. In some embodiments, the Joule heating treatment is performed in an inert gas ambient, such as N₂ and/or Ar.

In some embodiments, the conductive leads 85 connected to the conductive electrodes 55 are further connected to wires on the outside of the photolithography exposure apparatus, which are connected to the power supply 150.

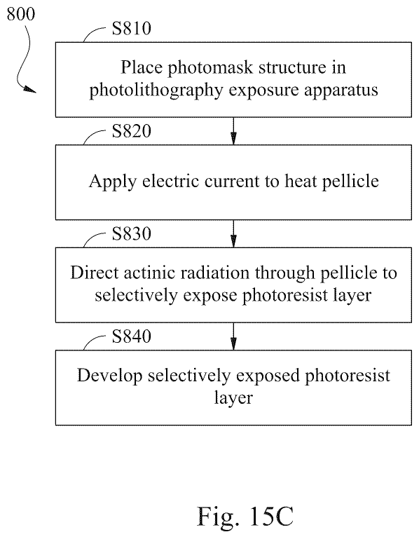

In some embodiments, as shown in FIG. 16, the Joule heating operation causes single separated nanotubes 100M (single or multi wall nanotubes) to join and form a bundle of nanotubes 100B having a seamless graphitic structure, in which the nanotubes are firmly bonded or joined more than merely contacting each other. Adjacent conductive nanotubes carrying current will attract each other through Ampere force. In some embodiments, three or more nanotubes are connected (bonded or joined) to form a bundle of nanotubes. The number of nanotubes in one bundle is up to 10, in some embodiments. The bundles provide stronger support for the membrane and increase the lifetime of membrane. The bundles increase the membrane's resistance to etching caused by hydrogen radicals and hydrogen ions generated during the photolithographic operations.

In some embodiments, the carbon nanotube membrane 100 as formed before the Joule heating treatment includes no or a small number of bundles of nanotubes, and after the Joule heating treatment, the number of the bundles of carbon nanotubes increases.

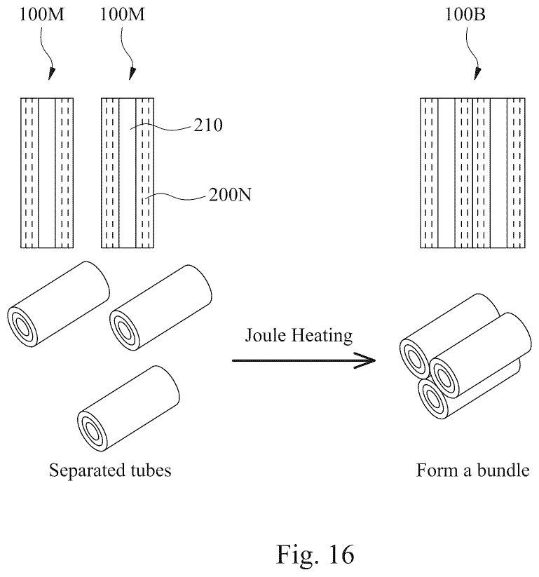

In some embodiments, the carbon nanotube membrane 100 as formed before the Joule heating treatment includes Sp³ carbon structure, such as amorphous carbon. As shown in FIG. 17, the Joule heating treatment removes the amorphous carbon from the membrane, and/or converts the amorphous carbon (Sp³ carbon structure) to a Sp² carbon structure. In some embodiments, the amorphous carbon is graphitized to form a crystalline structure. In some embodiments, the crystallized amorphous carbon forms one or more outer tubes surrounding an inner carbon nanotube, which have a single or multi wall structure, to form a multiwall nanotube. In some embodiments, an amount of the amorphous carbon in the membrane as formed before the Joule heating is in a range from about 1 wt. % to about 50 wt. %, and an amount of the amorphous carbon in the membrane after the Joule heating is less than about 3 wt. %. In some embodiments, the amount of the amorphous carbon in the membrane after the Joule heating is in a range from about 0.5 wt. % to about 2.5 wt. % based on the total weight of the membrane. In some embodiments, all the Sp³ carbon structures are removed or converted, and thus the membrane after the Joule heating treatment shows no peak at the D-band (1360 cm⁻¹) in a Raman spectroscopy. In other embodiments, a part of the Sp³ carbon structures remains, and a small peak at the D-band is observed. In some embodiments, the membrane includes Sp² carbon structure, such as graphite or graphene in the alternative or in addition to carbon nanotubes.

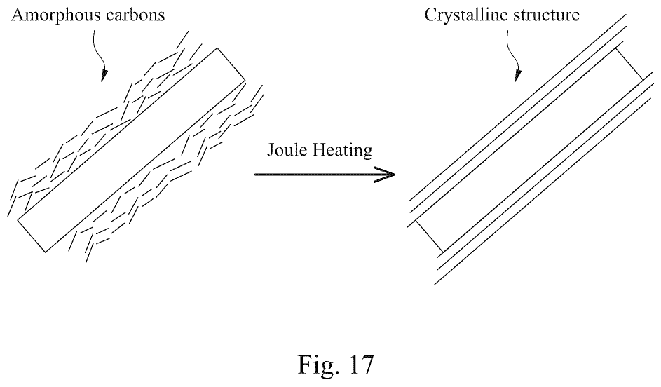

FIGS. 18A-18E show schematic views illustrating catalyst removal and bundle formation by the Joule heating treatment according to embodiments of the present disclosure.

As set forth above, a nanotube membrane 100 may include residual catalyst or catalyst particles 89 therein as shown in FIG. 18A. The Joule heating treatment can remove a part of (see FIG. 18B) or all (see FIG. 18C) the residual catalysts from the membrane. In addition, separate nanotubes as shown in FIG. 18A can be converted by the Joule heating treatment to bundles of nanotubes as shown in FIGS. 18D and 18E. In some embodiments, an amount of the residual catalysts in the membrane as formed before the Joule heating is in a range from about 7 wt. % to about 15 wt. % based on the total weight of the membrane, and an amount of the residual catalysts in the membrane after the Joule heating is less than about 2 wt. % based on the total weight of the membrane. In some embodiments, the amount of the residual catalysts in the membrane after the Joule heating is in a range from about 0.1 wt. % to about 1.5 wt. % based on the total weight of the membrane.

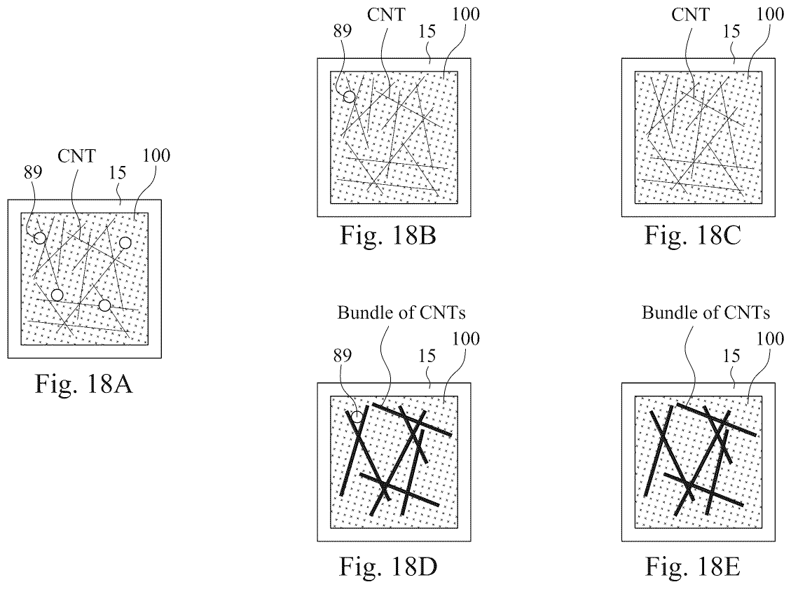

As shown in FIG. 19, in some embodiments the electric field generated at the pellicle repels contaminant particles 40 due to the electrostatic force, thereby preventing contamination of the pellicle, and the subsequent decrease of EUV radiation transmission.

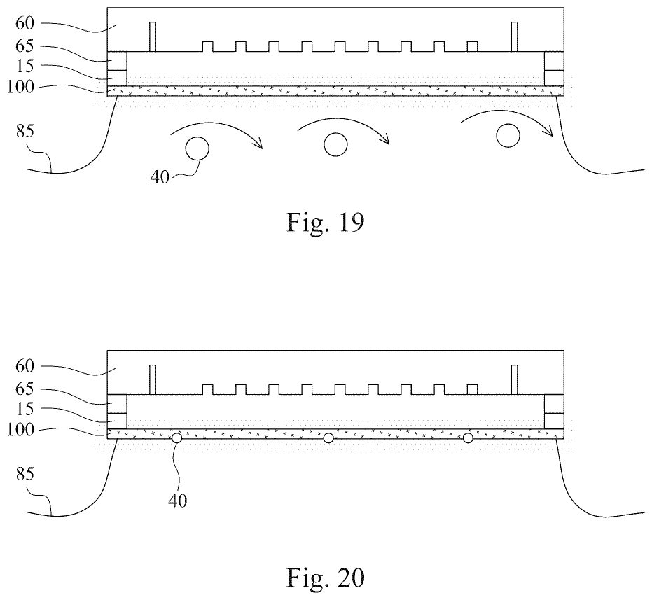

In other embodiments, the heat generated by the electric current is sufficient to decompose, vaporize, or burn contaminant particles 40 on the surface of the nanotube membrane 100, as shown in FIG. 20, thereby increasing the EUV radiation transmission of the pellicle 10.

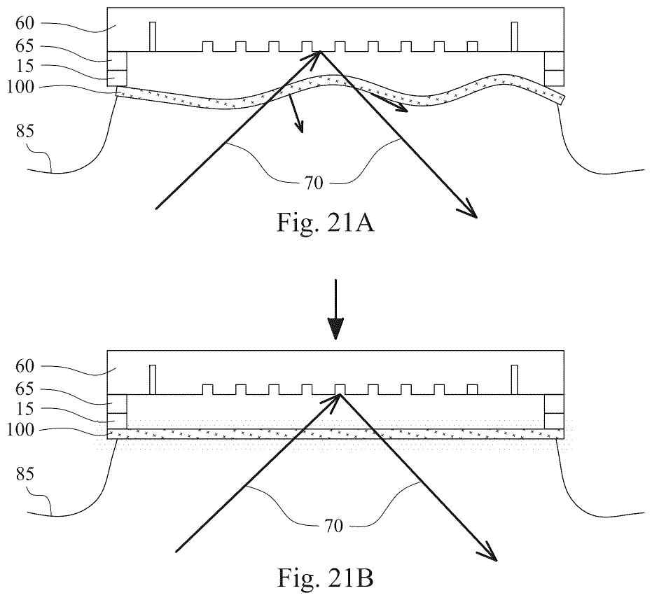

Embodiments of the present disclosure also reverse and prevent wrinkling of the nanotube membrane. As shown in FIG. 21A, wrinkles in the nanotube membrane may cause large deflections of the pellicle, which could induce breakage of the pellicle. Additionally, the wrinkles can also induce critical dimension (CD) error in the pattern to be formed because a portion of EUV radiation 70 may be reflected away from the intended radiation path by the wrinkles. Thus, the total energy exposing the photoresist layer will be reduced. As shown in FIG. 21B, applying a voltage across the nanotube membrane flattens the wrinkles. In some embodiments, a voltage of about 5 V to about 50 V is sufficient to reverse or prevent membrane wrinkling.

The Joule heating treatments according to the present disclosure also decreases the etching rate of the nanotube membrane. Hydrogen plasma including hydrogen ions and hydrogen radicals is produced by the EUV lithographic process. The hydrogen plasma etches carbon nanotubes and graphene in the membrane during the EUV lithographic process, thereby shortening the lifetime of the pellicle. The high temperature of the membrane caused by the Joule heating makes it harder for hydrogen ions and radicals to adhere to the pellicle, thereby retarding the hydrogen plasma etching rate.

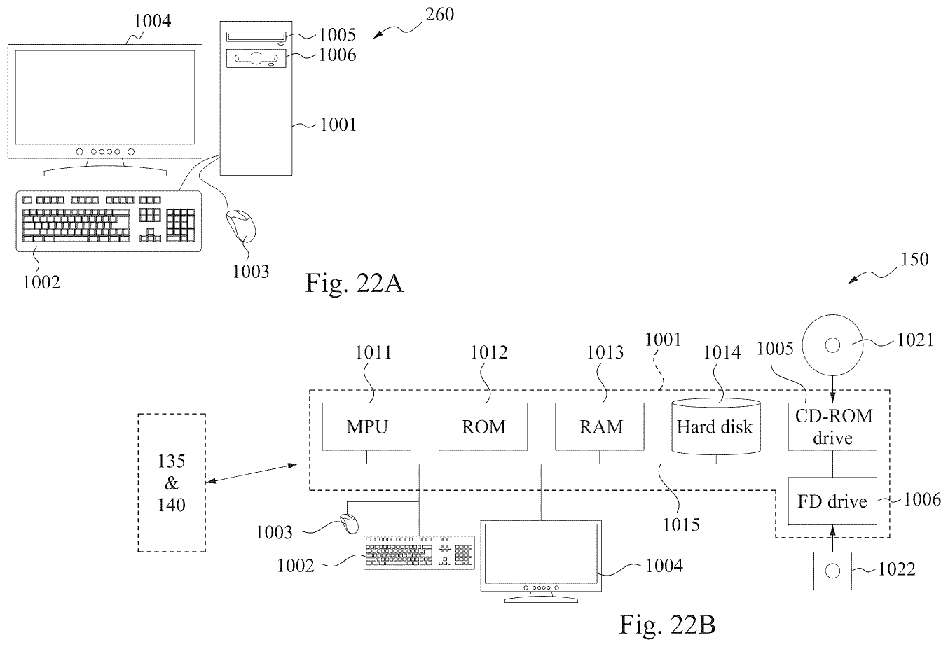

As explained above, a controller 150 is used to control the power supplied to the pellicle, and thus, the temperature of the nanotube membrane 100. In some embodiments, the controller 150 is a computer system. FIG. 22A and FIG. 22B illustrate a computer system 150 for controlling the power supply and applying current to the individual electrodes 55 in accordance with various embodiments of the disclosure. The controller 150 can also be used to control the heating operations S610, S720, and S820. In some embodiments, the controller is a module of a larger computer system that controls the other functions of the photolithographic exposure apparatus, including movement of the stepper/scanner, vacuum atmosphere, and the EUV radiation exposure of the photoresist-coated substrate. FIG. 22A is a schematic view of the computer system 150 that controls the power supply 135 and temperature sensor 140.

As shown in FIG. 22A, the computer system 150 is provided with a computer 1001 including an optical disk read only memory (e.g., CD-ROM or DVD-ROM) drive 1005 and a magnetic disk drive 1006, a keyboard 1002, a mouse 1003 (or other similar input device), and a monitor 1004 in some embodiments.

FIG. 22B is a diagram showing an internal configuration of the computer system 150. In FIG. 22B, the computer 1001 is provided with, in addition to the optical disk drive 1005 and the magnetic disk drive 1006, one or more processors 1011, such as a micro-processor unit (MP) or a central processing unit (CPU); a read-only memory (ROM) 1012 in which a program, such as a boot up program is stored; a random access memory (RAM) 1013 that is connected to the processors 1011 and in which a command of an application program is temporarily stored, and a temporary electronic storage area is provided; a hard disk 1014 in which an application program, an operating system program, and data are stored; and a data communication bus 1015 that connects the processors 1011, the ROM 1012, and the like. Note that the computer 1001 may include a network card (not shown) for providing a connection to a computer network such as a local area network (LAN), wide area network (WAN) or any other useful computer network for communicating data used by the computer system 150 and the power supply 135. In various embodiments, the controller 150 communicates via wireless or hardwired connection to the deposition apparatus 200, its components, and other tools used in the semiconductor device manufacturing operations.

The programs for causing the computer system 150 to execute the method for controlling the heating of the pellicle membrane 100 are stored in an optical disk 1021 or a magnetic disk 1022, which is inserted into the optical disk drive 1005 or the magnetic disk drive 1006, and transmitted to the hard disk 1014. Alternatively, the programs are transmitted via a network (not shown) to the computer system 150 and stored in the hard disk 1014. At the time of execution, the programs are loaded into the RAM 1013. The programs are loaded from the optical disk 1021 or the magnetic disk 1022, or directly from a network in various embodiments.

The stored programs do not necessarily have to include, for example, an operating system (OS) or a third-party program to cause the computer 1001 to execute the methods disclosed herein. The program may only include a command portion to call an appropriate function (module) in a controlled mode and obtain desired results in some embodiments. In various embodiments described herein, the controller 150 is in communication with the power supply 135 and temperature sensor 140 to control various functions thereof.

The controller 150 is configured to provide control data to the system components and receive process and/or status data from those system components. For example, in some embodiments, the controller 150 comprises a microprocessor, a memory (e.g., volatile or non-volatile memory), and a digital I/O port capable of generating control voltages sufficient to communicate and activate inputs to the processing system, as well as monitor outputs from the power supply 135 and temperature sensor 140. In addition, a process recipe may be stored the controller. Furthermore, the controller 150 is configured to analyze the process and/or status data, to compare the process and/or status data with target process and/or status data, and to use the comparison to change a process and/or control a system component. In addition, the controller 150 is configured to analyze the process and/or status data, to compare the process and/or status data with historical process and/or status data, and to use the comparison to predict, prevent, and/or declare a fault or alarm.

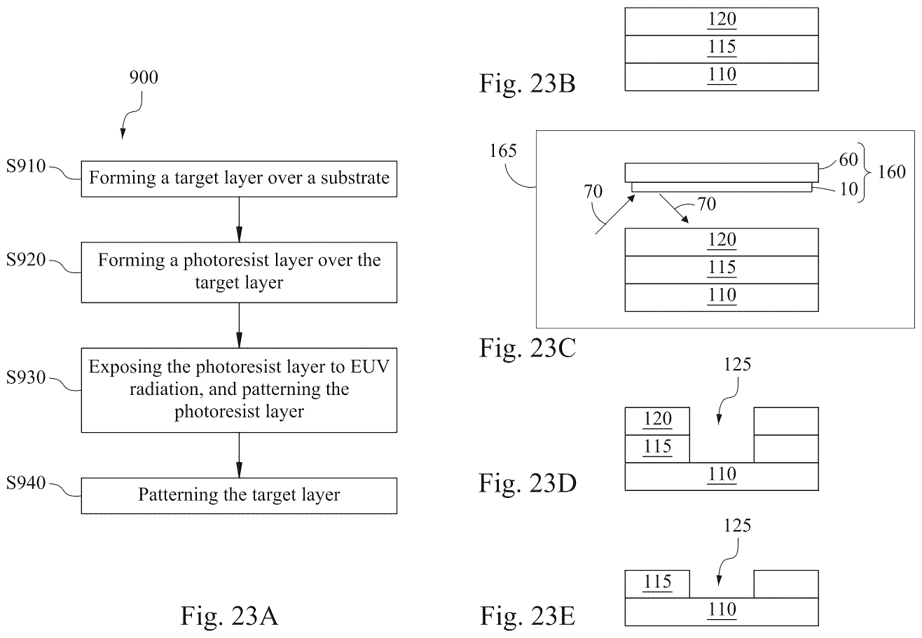

FIG. 23A shows a flowchart of a method 900 of making a semiconductor device, and FIGS. 23B, 23C, 23D and 23E show a sequential manufacturing method of making a semiconductor device in accordance with embodiments of present disclosure. A semiconductor substrate or other suitable substrate to be patterned to form an integrated circuit thereon is provided. In some embodiments, the semiconductor substrate includes silicon. Alternatively or additionally, the semiconductor substrate includes germanium, silicon germanium or other suitable semiconductor material, such as a Group III-V semiconductor material. At S910, of FIG. 23A, a target layer 115 to be patterned is formed over the semiconductor substrate 110. In certain embodiments, the target layer 115 is the semiconductor substrate. In some embodiments, the target layer 115 includes a conductive layer, such as a metallic layer or a polysilicon layer; a dielectric layer, such as silicon oxide, silicon nitride, SiON, SiOC, SiOCN, SiCN, hafnium oxide, or aluminum oxide; or a semiconductor layer, such as an epitaxially formed semiconductor layer. In some embodiments, the target layer 115 is formed over an underlying structure, such as isolation structures, transistors or wirings. At S920, a photoresist layer 120 is formed over the target layer, as shown in FIG. 23B. The photoresist layer 120 is sensitive to the radiation from the exposure radiation source during a subsequent photolithography exposing operation. In the present embodiment, the photoresist layer 120 is sensitive to EUV light used in the photolithography exposing operation. The photoresist layer 120 may be formed over the target layer 115 by spin-on coating or other suitable technique. The coated photoresist layer may be further baked to drive out solvent in the photoresist layer. At S930, the photoresist layer 120 is patterned in a photolithography exposure apparatus 165 using the pellicle/photomask structure 160, as set forth above, as shown in FIG. 23C. During the photolithography exposing operation, an integrated circuit (IC) design pattern defined on the photomask 60 is imaged to the photoresist layer 120 to form a latent pattern thereon. The patterning of the photoresist layer further includes developing the exposed photoresist layer to form a patterned photoresist layer having one or more openings 125. In one embodiment where the photoresist layer is a positive tone photoresist layer, the exposed portions of the photoresist layer are removed during the developing operation. The patterning of the photoresist layer may further include other operations, such as various baking operations at different stages. For example, a post-exposure-baking (PEB) process may be implemented after the photolithography exposure operation and before the developing operation.

At S940, the target layer 115 is patterned using the patterned photoresist layer 120 as an etching mask, as shown in FIG. 23D. In some embodiments, the patterning the target layer includes etching the target layer using the patterned photoresist layer as an etch mask. The portions of the target layer exposed within the openings of the patterned photoresist layer are etched while the remaining portions are protected from etching. Further, the patterned photoresist layer may be removed by wet stripping or plasma ashing, as shown in FIG. 23E.

Other embodiments include other operations before, during, or after the operations described above. In some embodiments, the disclosed methods include forming fin field effect transistor (FinFET) structures. In some embodiments, a plurality of active fins are formed on the semiconductor substrate. Such embodiments, further include etching the substrate through the openings of a patterned hard mask to form trenches in the substrate; filling the trenches with a dielectric material; performing a chemical mechanical polishing (CMP) process to form shallow trench isolation (STI) features; and epitaxy growing or recessing the STI features to form fin-like active regions. In some embodiments, one or more gate electrodes are formed on the substrate. Some embodiments include forming gate spacers, doped source/drain regions, contacts for gate/source/drain features, etc. In other embodiments, a target pattern is formed as metal lines in a multilayer interconnection structure. For example, the metal lines may be formed in an inter-layer dielectric (ILD) layer of the substrate, which has been etched to form a plurality of trenches. The trenches may be filled with a conductive material, such as a metal; and the conductive material may be polished using a process such as chemical mechanical planarization (CMP) to expose the patterned ILD layer, thereby forming the metal lines in the ILD layer. The above are non-limiting examples of devices/structures that can be made and/or improved using the method described herein.

In some embodiments, active components such diodes, field-effect transistors (FETs), metal-oxide semiconductor field effect transistors (MOSFET), complementary metal-oxide semiconductor (CMOS) transistors, bipolar transistors, high voltage transistors, high frequency transistors, sheet FETs, FinFETs, gate all around FETs (GAA FETs), other three-dimensional (3D) FETs, other memory cells, and combinations thereof are formed, according to embodiments of the disclosure.

In the foregoing embodiments, a pellicle membrane is subjected to a Joule heating operation to repel contaminants, remove contaminants, form bundles of nanotubes, and smoothing wrinkles in the membrane. The pellicles according to embodiments of the present disclosure provide higher strength, lower contamination, increased etching resistance, as well as higher EUV transmittance than conventional pellicles. As set forth above, embodiments of the present disclosure improve chemical and mechanical properties of a pellicle nanotube membrane.

It will be understood that not all advantages have been necessarily discussed herein, no particular advantage is required for all embodiments or examples, and other embodiments or examples may offer different advantages.

An embodiment of the disclosure is a method of manufacturing a semiconductor device, including heating a pellicle disposed over a photomask. Actinic radiation is directed through the pellicle to selectively expose a photoresist layer on a substrate. The selectively exposed photoresist layer is developed to form a pattern in the photoresist layer. In an embodiment, the heating is Joule heating. In an embodiment, the pellicle includes a layer including a plurality of nanotubes disposed over a frame. In an embodiment, the frame includes a plurality of conductive electrodes. In an embodiment, the heating the pellicle includes applying an electric current to the plurality of conductive electrodes. In an embodiment, the plurality of conductive electrodes include one or more first electrodes disposed on a first side of the frame and one or more second electrodes disposed on a second opposing side of the frame. In an embodiment, the plurality of conductive electrodes include one or more electrodes disposed on each side of the frame. In an embodiment, a voltage of 5 V to 500 V is applied to the plurality of conductive electrodes. In an embodiment, the pellicle is heated to a temperature ranging from 500° C. to 2000° C. In an embodiment, the pellicle is heated while the actinic radiation is directed through the pellicle.

Another embodiment of the disclosure is a method of manufacturing a semiconductor device, including selectively exposing a photoresist layer disposed on a substrate to actinic radiation. The actinic radiation passes through a pellicle disposed over a photomask and the actinic radiation is reflected from the photomask. An electrical current is applied to the pellicle to heat the pellicle while the actinic radiation passes through the pellicle. The selectively exposed photoresist layer is developed to form a pattern in the photoresist layer. In an embodiment, the pellicle includes a membrane comprising a plurality of nanotubes disposed over a frame, wherein the frame includes a plurality of conductive electrodes. In an embodiment, the plurality of nanotubes include carbon nanotubes. In an embodiment, the frame includes one or more conductive electrodes disposed on opposing sides of the frame. In an embodiment, the pellicle is heated to a temperature ranging from 500° C. to 2000° C. In an embodiment, the actinic radiation is extreme ultraviolet radiation.

Another embodiment of the disclosure is a method of manufacturing a semiconductor device, including placing a pellicle/photomask structure in a photolithography exposure apparatus. The pellicle/photomask structure includes a pellicle disposed over a photomask. The pellicle is heated by applying an electric current to the photomask structure through electrodes on a frame of the pellicle. Actinic radiation is directed from the photomask through the pellicle to selectively expose a photoresist layer disposed on a substrate. The selectively exposed photoresist layer is developed to form a pattern in the photoresist layer. In an embodiment, the pellicle includes a membrane including a plurality of carbon nanotubes disposed over the frame. In an embodiment, the pellicle is heated to a temperature ranging from 500° C. to 2000° C. In an embodiment, the actinic radiation is extreme ultraviolet radiation.

Another embodiment of the disclosure is a pellicle, including a transparent conductive membrane disposed over a frame. The frame includes two or more conductive electrodes disposed on the frame. In an embodiment, one or more conductive electrodes are disposed on opposing sides of the frame. In an embodiment, the transparent conductive membrane includes a plurality of nanotubes. In an embodiment, the plurality of nanotubes includes carbon nanotubes. In an embodiment, the plurality of nanotubes includes multiwall nanotubes. In an embodiment, the transparent conductive membrane allows extreme ultraviolet radiation to pass through.

Another embodiment of the disclosure is a pellicle having a membrane including a plurality of nanotubes disposed over a frame. The frame includes one or more conductive electrodes disposed on opposing sides of the frame. In an embodiment, the frame is a rectangular frame including one or more conductive electrodes disposed on each side of the frame. In an embodiment, the plurality of nanotubes includes carbon nanotubes. In an embodiment, the plurality of nanotubes includes multiwall nanotubes. In an embodiment, the frame is a rectangular frame and one or more conductive electrodes are disposed on each side of the frame. In an embodiment, the frame includes one or more layers of a crystalline silicon, a polysilicon, a silicon oxide, a silicon nitride, an aluminum oxide, or a ceramic. In an embodiment, a surface of the plurality of nanotubes includes crystallized carbon. In an embodiment, the conductive electrodes include copper, gold, nickel, silver, or alloys thereof. In an embodiment, the conductive electrodes are disposed between the nanotubes and the frame. In an embodiment, the pellicle includes a conductive lead connected to each conductive electrode.

Another embodiment of the disclosure is a pellicle, including a layer of carbon nanotubes disposed over a frame. Two or more electrodes are disposed between the frame and the layer of carbon nanotubes. A first electrode is disposed on a first side of the layer of carbon nanotubes and a second electrode is disposed on a second opposing side of the layer of carbon nanotubes along a length or a width of the layer of carbon nanotubes. A conductive lead extends from each electrode. In an embodiment, the layer of carbon nanotubes includes a plurality of bundles of carbon nanotubes, wherein the carbon nanotubes in each bundle of carbon nanotubes are connected to form a seamless graphite structure. In an embodiment, the layer of carbon nanotubes includes multiwall carbon nanotubes. In an embodiment, the frame is made of a crystalline silicon, a polysilicon, a silicon oxide, a silicon nitride, an aluminum oxide, or a ceramic. In an embodiment, the conductive electrodes include graphite or a metal selected from the group consisting of copper, gold, nickel, silver, or alloys thereof.

Another embodiment of the disclosure is a pellicle/photomask structure including a pellicle attached to a photomask. The pellicle includes a non-conductive frame, two or more electrodes disposed over the non-conductive frame, and a layer of nanotubes disposed over the non-conductive frame and the two or more electrodes. A first electrode is disposed on a first side of the layer of nanotubes and a second electrode is disposed on a second opposing side of the layer of nanotubes along a length or a width of the layer of nanotubes. In an embodiment, the photomask is a reflective photomask having a patterned surface and the pellicle is disposed over the patterned surface of the photomask. In an embodiment, the non-conductive frame is made of a crystalline silicon, a polysilicon, a silicon oxide, a silicon nitride, an aluminum oxide, or a ceramic. In an embodiment, the pellicle frame is attached to the photomask via an adhesive. In an embodiment, the layer of nanotubes includes multiwall nanotubes.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
placing a pellicle/photomask structure in a photolithography exposure apparatus,
wherein the pellicle/photomask structure comprises a pellicle disposed over a photomask;
heating the pellicle by applying an electric current to the pellicle/photomask structure through electrodes on a frame of the pellicle;
directing actinic radiation from the photomask through the pellicle to selectively expose a photoresist layer disposed on a substrate; and
developing the selectively exposed photoresist layer to form a pattern in the photoresist layer.

2. The method according to claim 1, wherein the pellicle includes a membrane comprising a plurality of carbon nanotubes disposed over the frame.

3. The method according to claim 2, wherein the plurality of carbon nanotubes includes multiwall carbon nanotubes.

4. The method according to claim 2, wherein:
two or more electrodes are disposed between the frame and the plurality of carbon nanotubes, and
a first electrode is disposed on a first side of the plurality of carbon nanotubes and a second electrode is disposed on a second opposing side of the plurality of carbon nanotubes.

5. The method according to claim 4, further comprising a conductive lead extending from each electrode.

6. The method according to claim 4, wherein a voltage of 5 V to 500 V is applied to the first electrode and the second electrode during the heating the pellicle by applying an electric current to the pellicle/photomask structure.

7. The method according to claim 1, wherein the actinic radiation is extreme ultraviolet radiation.

8. A pellicle, comprising:
a layer of carbon nanotubes disposed over a frame;
two or more electrodes disposed between the frame and the layer of carbon nanotubes,
wherein a first electrode is disposed on a first side of the layer of carbon nanotubes and a second electrode is disposed on a second opposing side of the layer of carbon nanotubes along a length or a width of the layer of carbon nanotubes; and
a conductive lead extending from each electrode.

9. The pellicle of claim 8, wherein the layer of carbon nanotubes includes a plurality of bundles of carbon nanotubes, wherein the carbon nanotubes in each bundle of carbon nanotubes are connected to form a seamless graphite structure.

10. The pellicle of claim 8, wherein the layer of carbon nanotubes includes multiwall carbon nanotubes.

11. The pellicle of claim 8, wherein the frame is made of a crystalline silicon, a polysilicon, a silicon oxide, a silicon nitride, an aluminum oxide, or a ceramic.

12. The pellicle of claim 8, wherein the conductive electrodes comprise graphite or a metal selected from the group consisting of copper, gold, nickel, silver, or alloys thereof.

13. The pellicle of claim 8, wherein the frame is a rectangular frame and one or more conductive electrodes are disposed on each side of the frame.

14. The pellicle of claim 13, wherein the conductive electrodes are disposed between the nanotubes and the frame.

15. The pellicle of claim 8, wherein a surface of the nanotubes comprises crystallized carbon.

16. A pellicle/photomask structure, comprising:
a pellicle attached to a photomask,
wherein the pellicle comprises:
a non-conductive frame;
two or more electrodes disposed over the non-conductive frame; and
a layer of nanotubes disposed over the non-conductive frame and the two or more electrodes,
wherein a first electrode is disposed on a first side of the layer of nanotubes and a second electrode is disposed on a second opposing side of the layer of nanotubes along a length or a width of the layer of nanotubes.

17. The pellicle/photomask structure of claim 16, wherein the photomask is a reflective photomask having a patterned surface and the pellicle is disposed over the patterned surface of the photomask.

18. The pellicle/photomask structure of claim 16, wherein the non-conductive frame is made of a crystalline silicon, a polysilicon, a silicon oxide, a silicon nitride, an aluminum oxide, or a ceramic.

19. The pellicle/photomask structure of claim 16, wherein the pellicle frame is attached to the photomask via an adhesive.

20. The pellicle/photomask structure of claim 16, wherein the layer of nanotubes includes multiwall nanotubes.
